(19) United States
(12) Patent Application Publication
(10) Pub. No.: US 2016/0293530 A1
(43) Pub. Date: Oct. 6, 2016

(54) SEMICONDUCTOR DEVICE

(71) Applicant: AISIN SEIKI KABUSHIKI KAISHA, Kariya-shi, Aichi (JP)

(72) Inventors: Minoru SHINOHARA, Anjo-shi (JP); Naoki NAKAMURA, Okazaki-shi (JP)

(73) Assignee: AISIN SEIKI KABUSHIKI KAISHA, Kariya-shi, Aichi (JP)

(21) Appl. No.: 15/034,688

(22) PCT Filed: Oct. 21, 2014
(86) PCT No.: PCT/JP2014/077956

§ 371 Date: May 5, 2016

(30) Foreign Application Priority Data
Nov. 8, 2013 (JP) 2013-232417

(51) Int. Cl. H01L 23/495; H01L 25/00; H01L 25/07

(52) U.S. Cl. CPC H01L 23/49575; H01L 23/49541; H01L 23/49503; H01L 25/072; H01L 25/50

(57) ABSTRACT

Provided is a semiconductor device which is compact and highly reliable. The semiconductor device includes a multi-gauge strip leadframe having a thick portion and thin portions thinner than the thick portion, a chip mounting portion on which a semiconductor chip is mounted, a relaying portion connected via a lead wire to a connecting portion provided in the semiconductor chip, and connecting terminals connected to the relaying portion. In the multi-gage strip leadframe, the thick portion is formed at a center portion in a Y direction of this multi-gauge strip leadframe, with a predetermined width along an X direction perpendicular to the Y direction, and the thin portions are formed on opposed sides of the thick portion in the X direction. The chip mounting portion is formed in the thick portion and the relaying portion is formed in the thick portion separately from the chip mounting portion. The connecting terminals are formed in the thin portions.

### RELATED ART

The present disclosure relates to a semiconductor device having a semiconductor chip mounted on a leadframe.

Conventionally, as one purpose of compactization of an electronic component, the art has utilized a semiconductor device having a plurality of semiconductor chips accommodated inside one package. An example of such semiconductor device is known from Patent Document 1 identified below.

The semiconductor device described in Patent Document 1 is a semiconductor device for driving a three-phase motor, wherein three sets of semiconductor chips each including a pair of pMISFET and nMISFET are mounted respectively on three tabs. A gate terminal and a source terminal of respective semiconductor chip are connected to a lead by wire bonding. Whereas, as to a drain terminal of respective semiconductor chip, drain terminals of semiconductor chips within a same tab are connected to each other via the leadframe and connected to the lead via this leadframe.

### Related Art Documents

### Patent Document

Patent Document 1: Japanese Unexamined Patent Application Publication No. 2007-12857

### SUMMARY

### Problem to be Solved by Invention

The semiconductor device described in Patent Document 1 employs a multi-gauge strip leadframe. In such leadframe, the semiconductor chips are mounted in a thick portion thereof and the lead is formed thinner than the portion where the semiconductor chips are mounted. Therefore, when the semiconductor elements and the lead are wire-bonded to each other, it is expected that a stress may be applied to the lead which is constituted of the thin portion of the leadframe. Therefore, there is possibility of deformation or even breakage of the leadframe, thus impairing the reliability of the semiconductor device.

In view of the above-described problem, the object of the present invention is to provide a semiconductor device that can provide high reliability even when this semiconductor device is formed compact.

### Solution

According to a characterizing feature of the present invention to achieve the above-noted object, a semiconductor device comprises:

a multi-gauge strip leadframe having a thick portion and thin portions thinner than the thick portion;

a chip mounting portion on which a semiconductor chip is mounted;

a relaying portion connected via a lead wire to a connecting portion provided in the semiconductor chip; and

connecting terminals connected to the relaying portion;

wherein in the multi-gage strip leadframe, the thick portion is formed at a center portion in a first direction of this multi-gauge strip leadframe, with a predetermined width along a second direction perpendicular to the first direction, and the thin portions are formed on opposed sides of the thick portion in the first direction; and

wherein the chip mounting portion is formed in the thick portion and the relaying portion is formed in the thick portion separately from the chip mounting portion, and the connecting terminals are formed in the thin portions.

With the above-described characterizing feature, even when a plurality of semiconductor chips are provided in one package, connecting between the semiconductor chips and the multi-gauge strip leadframe is effected in the thick portion, so that a stress generated in the multi-gauge strip leadframe at the time of connection with the lead wire can be reduced. Therefore, it becomes possible to realize a semiconductor device that provides high reliability even when this semiconductor device is formed compact.

Further, preferably, the thickness portion has a uniform thickness; and

when the multi-gauge strip leadframe is viewed from a mounting side of the semiconductor chip in a third direction perpendicular to the first direction and the second direction, the chip mounting portion is disposed on a farther side than the relaying portion along the third direction.

With the above-described arrangement, the chip mounting portion on which the semiconductor chip is mounted can be disposed close to a surface of the semiconductor device, so that heat generated from the semiconductor chip can be readily discharged.

Further, preferably, the chip mounting portion is disposed in U-shape in its plane view.

With the above-described arrangement, the distance between the chip mounting portion and the semiconductor chip can be reduced. Thus, a wire used for connecting the chip mounting portion and the semiconductor chip can be short, so that the material cost can be reduced advantageously. Moreover, loss due to joule heat can be reduced also.

Further, preferably, the relaying portion is formed to extend along the second direction forming an opening width of an opening of the U-shape.

With the above-described arrangement, the distance between the relaying portion and the semiconductor chip can be reduced. Thus, a wire used for connecting the relaying portion and the semiconductor chip can be short, so that the material cost can be reduced advantageously. Moreover, loss due to joule heat can be reduced also.

Further, preferably:

two said connecting terminals are connected to the relaying portion;

the thick portion and the thin portions are covered in a molded portion; and

the two connecting terminals are exposed in a predetermined common side face of the molded portion.

With the above-described arrangement, the connecting terminals can be provided parallel with each other, so that a current flowing in the connecting terminals can be divided, so loss due to joule heat can be reduced.

Further, preferably, one of the two connecting terminals is cut along a side face of the molded portion.

With the above-described arrangement, even when e.g. there is imposed a limit in the mounting area in a substrate on which the semiconductor device is to be mounted, as the number of the connecting terminals can be reduced, degree of freedom in mounting can be increased.

Further, preferably, on opposed sides in the second direction of the thick portion in the multi-gauge strip leadframe, there are formed fixing portions for fixing the multi-gauge strip leadframe to a device externally provided.

With the above-described arrangement, the semiconductor device can be fixed to an externally provided device. For instance, by fixing the substrate mounting the semiconductor device also at a predetermined position, a stress generated between the semiconductor device and the substrate can be reduced. Accordingly, the possibility of breakage of the connecting portion between the semiconductor device and the substrate can be reduced, whereby the reliability of the semiconductor device can be enhanced.

Further, preferably, in the thick portion, there is formed a grounding terminal insulated from the chip mounting portion and the relaying portion.

With the above-described arrangement, heat generated inside the semiconductor device can be readily conducted via this grounding terminal to the outside (e.g. to the substrate). Therefore, heat discharging performance of the semiconductor device can be enhanced. Moreover, in case the semiconductor chip is a switching device, the grounding performance of the semiconductor device can be enhanced by connecting the grounding terminal with the fixing portions. So that, transmission of switching noise from the semiconductor device to other device disposed in the circumference of this semiconductor device can be suppressed. Accordingly, adverse influence by switching noise to the other device can be reduced.

Further, preferably, on opposed side of the thick portion in the first direction, there are molded anchor portions extending along the second direction.

With the above-described arrangement, the tensile strength of the connecting terminal can be increased. Therefore, the reliability of the semiconductor device can be enhanced.

Further, preferably, between the chip mounting portion and the connecting terminal, the relaying portion is formed along the second direction.

With the above-described arrangement, the area of the relaying portion can be increased, so that the degree of freedom in the connection between the chip mounting portion and the relaying portion can be increased. Therefore, the connection between the chip mounting portion and the relaying portion can be carried out easily.

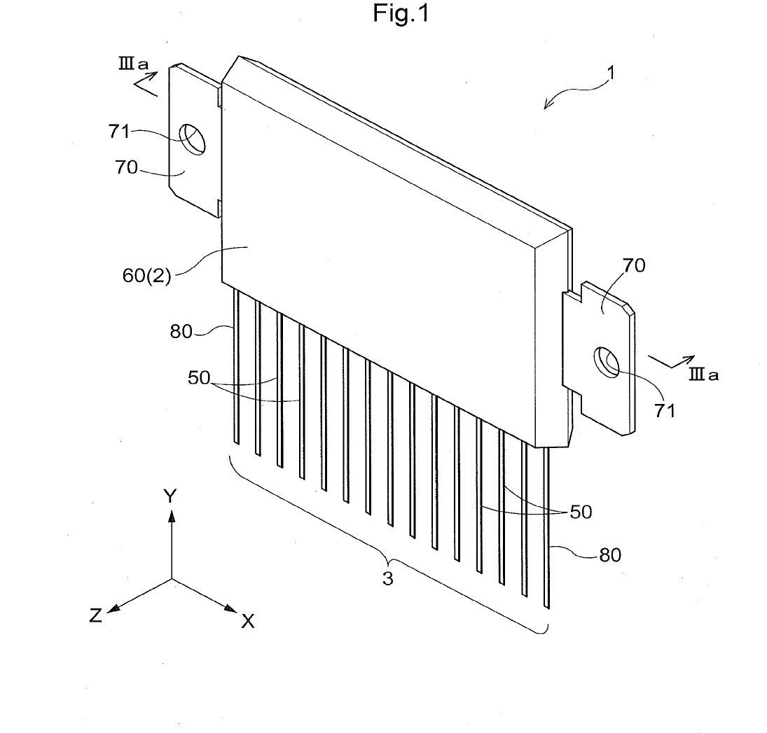

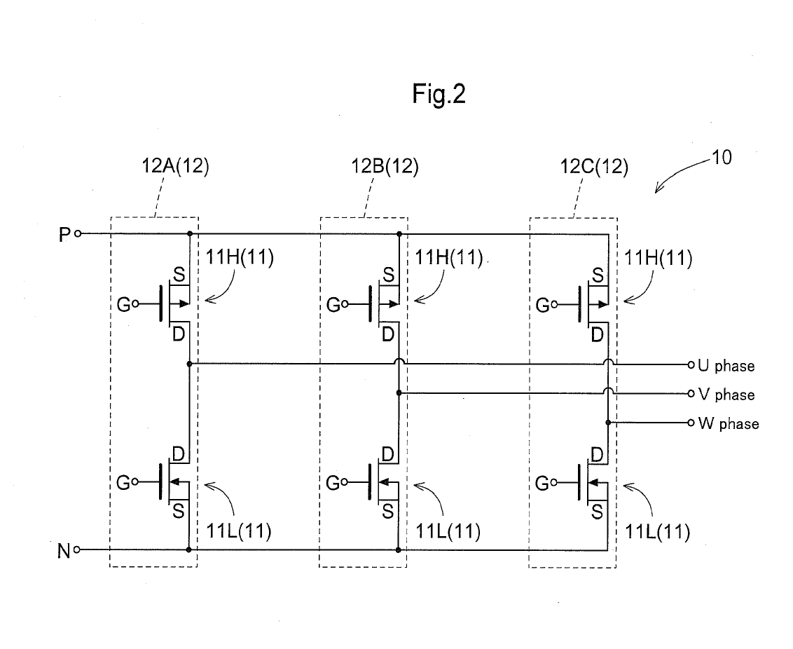

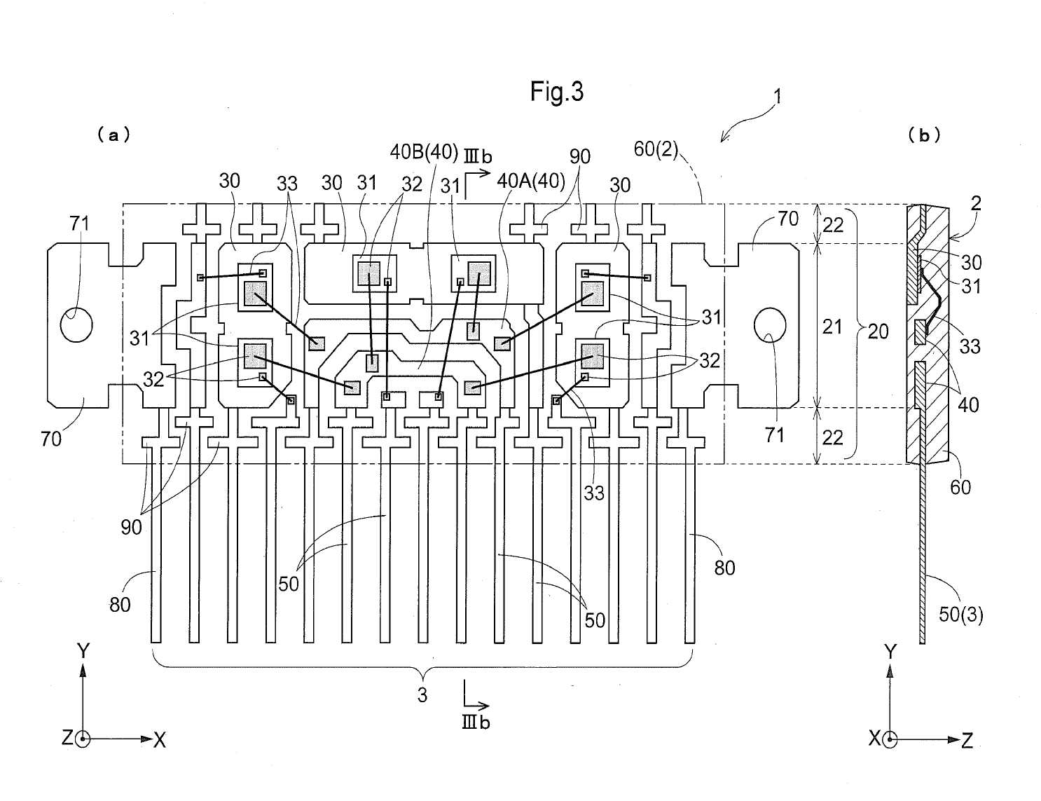

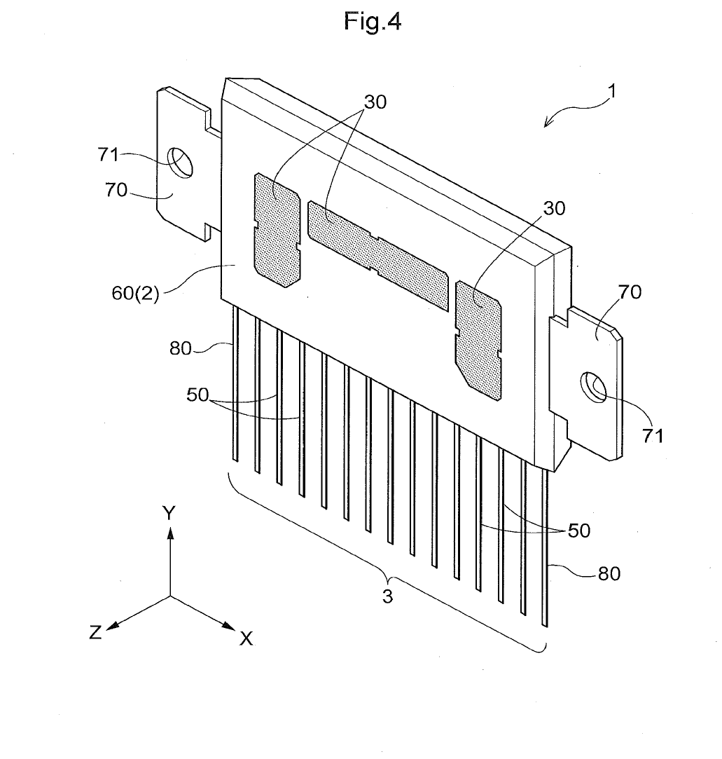

### BRIEF DESCRIPTION OF THE DRAWINGS

[FIG. 1] is a perspective view showing a front side of a semiconductor device,

[FIG. 2] is a circuit diagram showing mode of connecting of a semiconductor chip included in the semiconductor device,

[FIG. 3] is a section view showing respective portions of the semiconductor device,

[FIG. 4] is a perspective view showing a back side of the semiconductor device.

### EMBODIMENT

A semiconductor device relating to the present invention is configured to reduce a stress which will occur at the time of wire-bonding of a semiconductor chip. Next, a semiconductor device 1 according to this embodiment will be explained in details. FIG. 1 shows a perspective view of a front side of the semiconductor device 1.

The semiconductor device 1 according to this embodiment, as shown in FIG. 1, includes a main body portion 2 and lead terminals 3. The main body portion 2 is formed rectangular. The main body portion 2 corresponds to what will be referred to as a “molded portion 60” to be described later. And, in this molded portion 60, there are enclosed a plurality of semiconductor chips 31. The lead terminals 3 are provided by a number corresponding to a circuit arrangement of the semiconductor chips 31 enclosed in the main body portion 2. Each lead terminal 3 extends from one predetermined side face of the main body portion 2. Therefore, in the instant embodiment, the semiconductor device 1 is configured as a so-called substrate insert type component (DIP component). Incidentally, though the shape of the main body portion 2 is rectangular, it is understood that this shape is not particularly limited.

In the instant embodiment, the molded portion 60 encloses therein an inverter circuit 10. Such inverter circuit 10 is shown in FIG. 2. The inverter circuit 10 is a circuit for converting a DC power into a three-phase AC power for instance. The inverter circuit 10 includes a plurality of switching elements. As the switching elements, there can be employed FET (field effect transistor), IGBT (insulated gate bipolar transistor), etc. In the instant embodiment, as shown in FIG. 2, FETs 11 are employed as the switching elements.

The inverter circuit 10, as shown in FIG. 2, is provided between a positive power line P connected to the positive electrode of DC power source and a negative power line N (e.g. grounded potential) connected to the negative electrode of the DC power source. Between the positive power line P and the negative power line N, three sets (12A, 12B, 12C) of arm portions 12 to which high-side FET 11H and low-side FET 11L are serially connected are provided. Namely, each arm portion 12A, 12B, 12C is connected in parallel between the positive power line P and the negative power line N. In the instant embodiment, as the high-side FET 11H, P type FETs are employed, and as the low-side FET 11L, N type FETs are employed.

Such inverter circuit 10 as described above is used for providing power to respective stator coils corresponding to U phase, V phase and W phase of a rotary electric machine. Specifically, a midpoint of the arm portion 12A between the high-side FET 11H and the low-side FET 11L is connected to the U-phase stator coil of the rotary electric machine. And, a midpoint of the arm portion 12B between the high-side FET 11H and the low-side FET 11L is connected to the V phase stator coil of the rotary electric machine. Further, a midpoint of the arm portion 12C between the high-side FET 11H and the low-side FET 11L is connected to the W phase stator coil of the rotary electric machine.

A source terminal S of the high-side FET 11H of each arm portion 12A, 12B, 12C is connected to the positive power line P. And, a drain terminal D thereof is connected to a drain terminal D of the low-side FET 11L of the respective arm portion 12A, 12B, 12C. Further, a source terminal S of the low-side FET 11L of the respective arm portion 12A, 12B, 12C is connected to the negative power line N. Though not shown in FIG. 2, a diode is provided between the source terminal S and the drain terminal D of each FET 11. This diode has its cathode terminal connected to the source terminal S and has its anode terminal connected to the drain terminal D, respectively in the high-side FET 11H. On the other hand, in the low-side FET 11L, the cathode terminal is connected to the drain terminal D and the anode terminal is connected to the source terminal S.

In the above, in a same arm portion 12, when the high-side FET 11H and the low-side FET 11L are turned ON (power supplied state) simultaneously, the positive power line P and the negative power line N are short-circuited, so that the FET 11H and the FET 11L are controlled to be turned ON complimentarily each other. Such control is realized with input of control signals to the respective gate terminals G of the FET 11H and the FET 11L.

Next, a component layout of the FET 11 described above will be explained with reference to FIG. 3. FIG. 3(a) is a section view taken along a line IIIa-IIIa in FIG. 1. The semiconductor device 1 includes a multi-gauge strip leadframe 20, chip mounting portions 30, relaying portions 40, connecting terminals 50 and the molded portion 60.

The multi-gauge strip leadframe 20 includes a thick portion 21 formed at a center portion in a first direction with a predetermined width along a second direction perpendicular to the first direction, and thin portions 22 formed on the opposed outer sides of this thick portion 21 in the first direction and thinner than the thick portion 21. The first direction corresponds to the direction along which the lead terminals 3 extend in FIG. 3(a) and corresponds to a Y direction in FIG. 3(a). Therefore, the “center portion in a first direction” corresponds to a center portion in the Y direction. The language “a second direction perpendicular to the first direction” corresponds to an X direction perpendicular to the Y direction. The language “a predetermined width” means a width which is set in advance and this can be changed for each semiconductor device 1. Therefore, the thick portion 21 is formed at the center portion of the Y direction along the X direction perpendicular to this Y direction, in the multi-gauge strip leadframe 20.

The opposed outer sides of the thick portion 21 in the first direction refer to the opposed outer sides of the thick portion 21 along the Y direction. Therefore, the thin portions 22 are formed to sandwich the thick portion 21 along the Y direction. Further, the thickness of the thin portions 22 is set smaller than the thickness of the thick portion 21. Therefore, the thick portion 21 has a greater thickness than the thin portions 22. Accordingly, the multi-gauge strip leadframe 20 is configured as a strip-like component having a thick plate portion and thin plate portions in the Y direction. Such multi-gauge strip leadframe 20 can be made by rolling of copper, copper alloy or the like for instance.

The chip mounting portion 30 is formed on the thick portion 21 and the semiconductor chip(s) 31 is mounted thereon. The thick portion 21 is a region formed at the center portion in the Y direction in the multi-gauge strip leadframe 20 as described above and having a greater thickness than the thin portions 22 on the outer sides in the Y direction. The semiconductor chip 31 is a component formed by dicing each one of the plurality of FETs 11 made in a semiconductor wafer. The FET 11 diced from such semiconductor wafer is mounted on the thick portion 21 of the multi-gauge strip leadframe 20. Here, the chip mounting portion 30 is formed of a same material as the multi-gauge strip leadframe 20. In each FET 11, the drain terminal D is formed to be exposed in the back face thereof. The FET 11 is mounted on the chip mounting portion 30 in such a manner that the drain terminal D thereof is oriented towards the side of the chip mounting portion 30 and electrically connected with this chip mounting portion 30. In the instant embodiment, three chip mounting portions 30 are formed on the multi-gauge strip leadframe 20, and the high-side FET 11H and the low-side FET 11L of each one of the arm portions 12A, 12B, 12C are paired and mounted as such on the chip mounting portions 30.

Further, in the instant embodiment, the chip mounting portion 30 is disposed in U-shape in the plane view as shown in FIG. 3 (a). Here, “U-shape in the plane view” means that when the multi-gauge strip leadframe 20 is viewed from the above, the chip mounting portion 30 is disposed in a form similar to the alphabet letter “U”.

The relaying portion 40 is formed in the thick portion 21 separately from the chip mounting portion 30 and is connected to a connecting portion 32 provided in the semiconductor chip 31 via a lead wire 33. The relaying portion 40 is formed in the thick portion 21 in the multi-gauge strip leadframe 20, like the chip mounting portion 30. The language” formed . . . separately from the chip mounting portion 30″ means that as shown in FIG. 3(a), when the multi-gauge strip leadframe 20 is viewed along a Z direction, the relaying portion 40 and the chip mounting portion 30 are formed like separate islands. In the instant embodiment, two such relaying portions 40 are formed in the multi-gauge strip leadframe 20.

The connecting portion 32 provided in the semiconductor chip 31 refers to two of three terminals provided in the FET 11 other than the terminal exposed in the back face of the FET 11. In the instant embodiment, these correspond to the gauge terminal G and the source terminal S of the FET 11. The lead wire 33 refers to a length of wire used for the known wire-bonding arrangement. Of the two relaying portions 40, to one relaying portion 40A, the source terminal S of the high-side FET 11H is electrically connected via the lead wire 33 by wire-bonding and to the other relaying portion 40B, the source terminal S of the low-side FET 11L is electrically connected with the lead wire 33 by wire-bonding. Therefore, each relaying portion 40 relays the positive power line P with the negative power line N connected to the FET 11. That is, the FET 11 is connected to the positive power line P and the negative power line N via the relaying portions 40.

Further, in the instant embodiment, the relaying portion 40, as shown in FIG. 3(a), is formed to extend along a second direction forming the opening width of the opening of the U-shape of the chip mounting portion 30. Here, the opening of the U-shape means a portion where the chip mounting portion 30 is not disposed, when the circumference is viewed around the center portion of the area where the plurality of chip mounting portions 30 are disposed in the U-shape. The second direction forming the opening width of the opening means the direction of spacing distance between the portions where the chip mounting portion 30 is not disposed and this corresponds to the Y direction in FIG. 3(a). Therefore, the relaying portion 40 is formed along the spacing distance direction of the opening of the chip mounting portions 30 disposed in such U-shape layout. Incidentally, the relaying portion 40 can be formed like a bar along the spacing distance direction of such U-shape or can be formed in the U-shape also.

The connecting terminal 50 is formed in the thin portions 22 and connected to the relaying portion 40. The thin portions 22 refer to portions formed on the outer sides in the Y direction of the thick portion 21 so as to sandwich this thick portion 21 therebetween in the multi-gauge strip leadframe 20 and which is thinner than the thick portion 21. Therefore, the connecting terminal 50 is formed thinner than the thick portion 21. This connecting terminal 50 constitutes a part of the lead terminal 3 described above.

Further, from the chip mounting portion 30 too, a connecting terminal 50 is formed to extend in the same direction as the connecting terminal 50 connected to the above-described relaying portion 40. However, this connecting terminal 50 extending from the chip mounting portion 30 is formed to extend not via the relaying portion 40. And, such connecting terminal 50 extending from the chip mounting portion 30 is provided also in the thin portion 22.

Further, the gate terminal G of each FET 11 is connected to a predetermined portion of the thin portion 22 by wire-bonding with the lead wire 33. Here, “a predetermined portion” is not particularly limited, but it means that the portion can change according to layout of each semiconductor chip 31. And, from such portion wire-bonded with the gate terminal G too, a connecting terminal 50 is formed to extend in the same direction as the connecting terminal 50 extending from the chip mounting portion 30 described above. Therefore, these connecting terminals 50 correspond to the above-described lead terminals 3. And, between such chip mounting portion 30 and the connecting terminal 50, the relaying portion 40 is disposed along the second direction.

Here, the thick portion 21 is configured with a uniform thickness. The language “uniform thickness” means that the thickness of the thick portion 21 is constant within the plane of this thick portion 21, without any thinning. The chip mounting portion 30 is disposed such that when the multi-gauge strip leadframe 20 is viewed from the side where the semiconductor chip 31 is mounted in the third direction perpendicular to the first direction and the second direction, the chip mounting portion 30 is disposed on the farther side along the third direction than the relaying portion 40. As described above, the first direction is the Y direction in FIG. 3(a) and the second direction is the X direction. Therefore, the third direction perpendicular to the first direction and the second direction corresponds to the Z direction perpendicular to both the X direction and the Y direction. Therefore, the language “when the multi-gauge strip leadframe 20 is viewed from the side where the semiconductor chip 31 is mounted in the third direction” means that the multi-gauge strip leadframe 20 is viewed from above the face on which the semiconductor chip 31 is mounted. Thus, the chip mounting portion 30, as shown in FIG. 3(b) which is a section taken along a line IIIb-IIIb in FIG. 3(a), is formed such that when the multi-gauge strip leadframe 20 is viewed from above the face on on which the semiconductor chip 31 is mounted, the relaying portion 40 is present on the near side and the chip mounting portion 30 is disposed on the far side. Therefore, as shown in FIG. 4, it becomes possible to expose the back face of the chip mounting portion 30 to the outside from the molded portion 60.

Here, preferably, a known half-edge can be formed at the outer edge portion of the back face of the chip mounting portion 30. With such half edge, as shown in FIG. 4, the back face of the chip mounting portion 30 can be exposed for its entire area from the molded portion 60.

Such thick portion 21 and the thin portions 22 are covered with resin. And, this covering resin corresponds to the molded portion 60.

Here, in the instant embodiment, two connecting terminals 50 are connected to each relaying portion 40. In the instant embodiment, the semiconductor device 1 comprises a DIP component. Therefore, the lead terminals 3 including the two connecting terminals 50 will be provided to be exposed in a predetermined common side of the molded portion 60. Namely, the lead terminals 3 are provided to extend from the predetermined same side face of the molded portion 60.

Further, in the instant embodiment, on the opposed sides in the second direction of the thick portion 21 in the multi-gauge strip leadframe 20, there are formed fixing portions 70 which fix the multi-gauge strip leadframe 20 to an externally provided device. The second direction means the X direction. An “externally provided device” can be e.g. a box of a unit in which the semiconductor device 1 is to be mounted. The fixing portions 70 are provided to project from the molded portion 60 in the X direction and holes 71 of a predetermined shape are formed therein. Accordingly, the semiconductor device 1 can be fastened and fixed with screws to e.g. the box of the unit in which the semiconductor device 1 is to be mounted, via the hole portions 71 formed in the fixing portions 70 projecting to the outer sides in the X direction of the thick portion 21 of the multi-gauge strip leadframe 20. Needless to say, the hole portions 71 can be provided as portions which are cut out in a predetermined shape.

Further, in the instant embodiment, in the thick portion 21, there is formed a grounding terminal 80 insulated from the chip mounting portion 30 and the relaying portion 40. The language “insulated from the chip mounting portion 30 and the relaying portion 40” means as shown in FIG. 3(a) that the grounding terminal 80 is separated from both the chip mounting portion 30 and the relaying portion 40, thus being formed like an island. Such grounding terminal 80 is provided to extend from the same face of the molded portion 60 where the lead terminals 3 are provided and can be electrically connected to the above-described fixing portion 70 in the molded portion 60. With this, as the box to which the above-described fixing portion 70 is fastened and fixed is grounded, the grounding terminal provided on the substrate on which the semiconductor device 1 is mounted can be set via this semiconductor device 1. Further, with the above, the FET 11 acting as a switching element can be sandwiched by the grounding terminals in the X direction, it becomes possible to reduce adverse influence of switching noise of the FET 11 to the components disposed around the semiconductor device 1.

Further, in the instant embodiment, on the opposed sides of the thick portion 21 in the first direction, there are molded anchor portions 90 that extend in the second direction. The first direction is the Y direction and the second direction is the X direction. The anchor portion 90 is a portion which functions as an anti-withdrawal mechanism for preventing inadvertent withdrawal when pulled in the extending direction of the connecting terminals 50 and this is a wide portion of the lead terminal 3 which portion is formed wider than the width in the X direction. And, such anchor portions 90 are formed in the thin portion 22 and enclosed inside the molded portion 60. Wth this arrangement, anti-withdrawal resistance of the lead terminal 3 in the Y direction can be increased, so that the reliability of the semiconductor device 1 can be improved.

### Other Embodiments

In the foregoing embodiment, it was explained that the inverter circuit 10 is enclosed in the semiconductor device 1. However, the range of application of the present invention is not limited thereto. The semiconductor device 1 can enclose a circuit other than the inverter circuit 10 also or can enclose only one semiconductor chip 31.

In the foregoing embodiment, it was explained that the P type FET is employed as the high-side FET 11H and the N type FET is employed as the low-side FET 11L, to constitute the inverter circuit 10. However, the range of application of the present invention is not limited thereto. Alternatively, both the high-side FET 11H and the low-side FET 11L can be constituted of the P type FETs, or both the high-side FET 11H and the low-side FET 11L can be constituted of the N type FETs. Further alternatively, the high-side FET 11H can be constituted of the N-type FET and the low-side FET 11L can be constituted of the P type FET.

In the foregoing embodiment, it was explained that the thick portion 21 has a uniform thickness. However, the range of application of the present invention is not limited thereto. Alternatively, the thick portion 21 can have various thicknesses at respective parts thereof.

In the foregoing embodiment, it was explained that the chip mounting portion 30 is formed such that when the multi-gauge strip leadframe 20 is viewed from above the face on on which the semiconductor chip 31 is mounted in the third direction, the chip mounting portion 30 is disposed on the farther side along the third direction than the relaying portion 40. However, the range of application of the present invention is not limited thereto. Alternatively, the chip mounting portion 30 and the relaying portion 40 can be disposed at same positions in the third direction.

In the foregoing embodiment, it was explained that the number of the connecting terminals 50 provided in the chip mounting portion 30 is two. However, the range of application of the present invention is not limited thereto. Alternatively, only one connecting terminal 50 can be provided in the chip mounting portion 30.

In the foregoing embodiment, it was explained that two connecting terminals 50 are exposed in a predetermined common side face of the molded portion 60. However, the range of application of the present invention is not limited thereto. Alternatively, the two connecting terminals 50 can be exposed in different faces of the molded portion 60, respectively.

In the foregoing embodiment, it was explained that two connecting terminals 50 are provided to extend along the X direction. However, the range of application of the present invention is not limited thereto. Alternatively, one of the two connecting terminals 50 can be cut along a side face of the molded portion 60. Namely, in this case, only one of the two connecting terminals 50 will be provided to extend from the molded portion 60. With this arrangement, it is possible to reduce the number of through holes though which the lead terminals 3 are to be inserted through the substrate mounting the semiconductor device 1.

In the foregoing embodiment, it was explained that the fixing portions 70 are fixed to the outer sides of the thick portion 21 in the X direction in the multi-gauge strip leadframe 20. However, the range of application of the present invention is not limited thereto. Alternatively, the semiconductor device 1 can be configured without the fixing portions 70. Or, the fixing portion 70 can be provided on only one outer side in the X direction of the thick portion 21.

In the foregoing embodiment, it was explained that in the thick portion 21, there is formed the grounding terminal 80 insulated from the chip mounting portion 30 and the relaying portion 40. However, the range of application of the present invention is not limited thereto. Needless to say, the semiconductor device 1 can be configured without such grounding terminal 80, also.

In the foregoing embodiment, it was explained that the anchor portion 90 is formed of a wide portion having a greater width than the width of the lead terminal 3 in the X direction. However, the range of application of the present invention is not limited thereto. Alternatively, the anchor portion 90 can be formed with the same width as the lead terminal 3 and can be constituted of e.g. a bent portion bent to be non-parallel with the Y direction.

In the foregoing embodiment, it was explained that the anchor portions 90 are formed on the opposed outer sides in the Y direction of the thick portion 21. However, the range of application of the present invention is not limited thereto. Alternatively, the semiconductor device 1 can be configured without such anchor portions 90, also.

In the foregoing embodiment, it was explained that the chip mounting portion 30 is disposed in U-shape in its plane view. However, the range of application of the present invention is not limited thereto. Alternatively, the chip mounting portion 30 can be disposed in any other shape than the U-shape in its plane view.

In the foregoing embodiment, it was explained that the relaying portion 40 is formed to extend along the opening width of the opening of the U-shape of the chip mounting portion 30. However, the range of application of the present invention is not limited thereto. Alternatively, the relaying portion 40 can be formed to extend not along the opening width of the opening of the U-shape of the chip mounting portion 30.

### INDUSTRIAL APPLICABILITY

The present invention is applicable to a semiconductor device having a semiconductor chip mounted on a leadframe.

### DESCRIPTION OF REFERENCE MARKS/NUMERALS

1: semiconductor device

20: multi-gauge strip leadframe

21: thick portion

22: thin portion

30: chip mounting portion

31: semiconductor chip

32: connecting portion

33: lead wire

40: relaying portion

50: connecting terminal

60: molded portion

70: fixing portion

80: grounding terminal

90: anchor portion

1. A semiconductor device comprising:
a multi-gauge strip leadframe having a thick portion and thin portions thinner than the thick portion;
a chip mounting portion on which a semiconductor chip is mounted;
a relaying portion connected via a lead wire to a connecting portion provided in the semiconductor chip; and
connecting terminals connected to the relaying portion;
wherein in the multi-gage strip leadframe, the thick portion is formed at a center portion in a first direction of this multi-gauge strip leadframe, with a predetermined width along a second direction perpendicular to the first direction, and the thin portions are formed on opposed sides of the thick portion in the first direction; and
wherein the chip mounting portion is formed in the thick portion and the relaying portion is formed in the thick portion separately from the chip mounting portion, and the connecting terminals are formed in the thin portions.

2. The semiconductor device according to claim 1, wherein:
the thickness portion has a uniform thickness; and
when the multi-gauge strip leadframe is viewed from a mounting side of the semiconductor chip in a third direction perpendicular to the first direction and the second direction, the chip mounting portion is disposed on a farther side than the relaying portion along the third direction.

3. The semiconductor device according to claim 1, wherein the chip mounting portion is disposed in U-shape in its plane view.

4. The semiconductor device according to claim 3, wherein the relaying portion is formed to extend along the second direction forming an opening width of an opening of the U-shape.

5. The semiconductor device according to claim 1, wherein:
two said connecting terminals are connected to the relaying portion;
the thick portion and the thin portions are covered in a molded portion; and
the two connecting terminals are exposed in a predetermined common side face of the molded portion.

6. The semiconductor device according to claim 5, wherein one of the two connecting terminals is cut along a side face of the molded portion.

7. The semiconductor device according to claim 1, wherein on opposed sides in the second direction of the thick portion in the multi-gauge strip leadframe, there are formed fixing portions for fixing the multi-gauge strip leadframe to a device externally provided.

8. The semiconductor device according to claim 1, wherein in the thick portion, there is formed a grounding terminal insulated from the chip mounting portion and the relaying portion.

9. The semiconductor device according to claim 1, wherein on opposed side of the thick portion in the first direction, there are molded anchor portions extending along the second direction.

10. The semiconductor device according to claim 1, wherein between the chip mounting portion and the connecting terminal, the relaying portion is formed along the second direction.
